(19) United States
(12) Patent Application Publication
(10) Pub. No.: US 2026/0079195 A1
(43) Pub. Date: Mar. 19, 2026

(54) SEMICONDUCTOR TESTING APPARATUS

(71) Applicant: Kioxia Corporation, Tokyo (JP)

(72) Inventor: Yuto FUJIMURA, Fujisawa Kanagawa (JP)

(73) Assignee: Kioxia Corporation, Tokyo (JP)

(21) Appl. No.: 19/063,418

(22) Filed: Feb. 26, 2025

(30) Foreign Application Priority Data
Sep. 13, 2024 (JP) 2024-159564

(51) Int. Cl. G01R 31/28

(52) U.S. Cl. CPC G01R 31/2841; G01R 31/2882

(57) ABSTRACT

The semiconductor testing apparatus according to an embodiment includes a plurality of signal generators that apply a test signal to each of a plurality of IF of a device under test, and a signal generation controller that compiles a signal including basic timing information and pattern information for a test item to be measured into a data signal, and performs timing adjustment of the test signal by setting timing information based on the data signal.

### CROSS-REFERENCE TO RELATED APPLICATION(S)

This application is based upon and claims the benefit of priority from the prior Japanese Patent Application No. 2024-159564, filed on Sep. 13, 2024, the entire contents of which are incorporated herein by reference.

### FIELD

Embodiments of the present disclosure relate to a semiconductor testing apparatus.

### BACKGROUND

In order to realize high-speed performance, a semiconductor apparatus exists having a plurality of IF. A semiconductor testing apparatus for testing whether or not such a semiconductor apparatus satisfies a predetermined design specification includes a plurality of signal generators for testing the plurality of IF at the same time. In order to perform a test to measure timing definitions between the plurality of IF, it is required to synchronize times between the plurality of signal generators in the semiconductor testing apparatus. When this synchronization is performed, with the plurality of signal generators, synchronization is achieved by making a leading device wait until the most delayed device completes signal generation.

### BRIEF DESCRIPTION OF THE DRAWINGS

FIG. 1 is a schematic configuration diagram of a semiconductor testing apparatus according to an embodiment of the present disclosure.

FIG. 2 is a schematic configuration diagram of a signal generator according to an embodiment of the present disclosure.

FIG. 3 is a flowchart for explaining test execution by a semiconductor testing apparatus according to an embodiment of the present disclosure.

FIG. 4 is a timing chart for explaining signal generation by a semiconductor testing apparatus according to an embodiment of the present disclosure.

FIG. 5 is a timing chart for explaining signal generation by a semiconductor testing apparatus according to an embodiment of the present disclosure.

### DESCRIPTION OF EMBODIMENTS

Hereinafter, a semiconductor testing apparatus according to the present embodiment will be described in detail with reference to the drawings. In the following description, elements having substantially the same functions and configurations are denoted by the same reference signs or the same reference signs followed by letters, and will be described redundantly only when necessary. Each of the embodiments described below exemplifies an apparatus and a method for embodying the technical idea of this embodiment. Various modifications may be made to the embodiments without departing from the spirit of the disclosure. These embodiments and modifications thereof are included in the scope of the disclosure described in the claims and equivalents thereof.

In the drawings, although the widths, thicknesses, shapes, and the like of the respective portions may be schematically represented in comparison with the actual embodiments for clarity of explanation, the drawings are merely examples, and do not limit the interpretation of the present disclosure. In the present specification and the drawings, elements having the same functions as those described with respect to the previous drawings are denoted by the same reference signs, and redundant descriptions thereof may be omitted.

In the present specification, the expression “α includes A, B, or C” does not exclude a case where α includes a plurality of combinations of A to C unless otherwise specified. Furthermore, these expressions do not exclude the case where α includes other elements.

The following embodiments can be combined with each other as long as there is no technical inconsistency.

A semiconductor testing apparatus according to an embodiment includes a plurality of signal generators that apply a test signal to each of a plurality of interfaces of a device under test, and a signal generation controller that compiles a signal including basic timing information and pattern information for a test item to be measured into a data signal, and performs timing adjustment of the test signal by setting timing information based on the data signal.

### First Embodiment

### [Structure of Semiconductor Testing Apparatus]

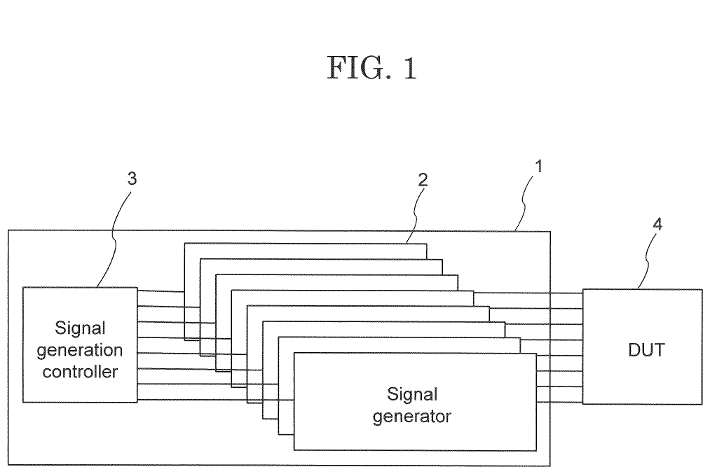

FIG. 1 is a schematic configuration diagram of a semiconductor testing apparatus according to the present embodiment.

A semiconductor testing apparatus 1 according to the present embodiment includes a signal generator 2 and a signal generation controller 3. The signal generator 2 and the signal generation controller 3 are connected by a bus, and the signal generator 2 and the signal generation controller 3 constitute a waveform generator. The waveform generator is a device that generates and outputs an arbitrary waveform, and can be applied to various apparatuses, and a case where the waveform generator is applied to a semiconductor testing apparatus will be described. The semiconductor testing apparatus 1 includes a waveform generator for sequentially generating patterns based on a certain algorithm from read or write data signals and address signals for memory cells of a DUT 4 (Device Under Test) to perform pass/fail judgments.

The signal generator controller 3 is a device for controlling the signal generator 2, and controls the signal generator 2 to output a desired waveform. The signal generation controller 3 controls the signal generator 2 by outputting control data via a bus. The DUT 4 is an object for inputting a wave form and is pin-connected to the signal generator 2.

The signal generator 2 is a circuit board including components for generating waveforms. The semiconductor testing apparatus 1 includes a plurality of signal generators 2. Although eight signal generators 2 are arranged in FIG. 1, the present disclosure is not limited thereto. Each part for generating and outputting a waveform is mounted on the signal generator 2. The plurality of signal generators 2 can generate different waveforms.

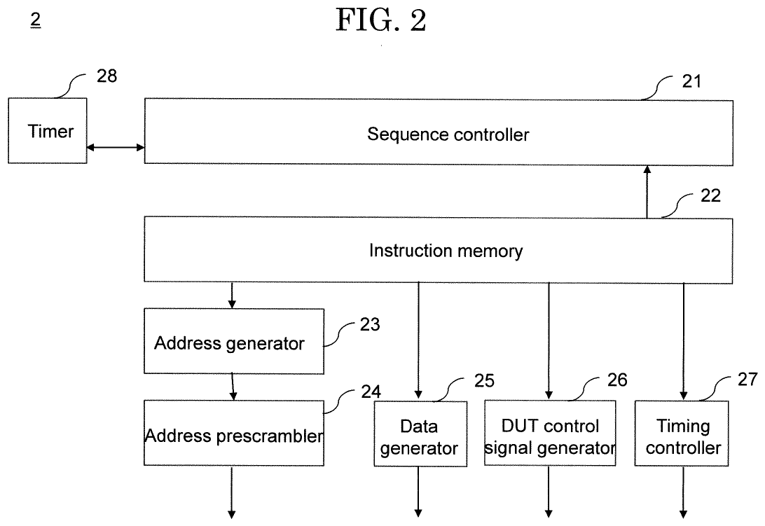

FIG. 2 shows a schematic configuration of the signal generator 2. As shown in FIG. 2, the signal generator 2 includes a sequence controller 21, an instruction memory 22, an address generator 23, an address prescrambler 24, a data generator 25, a DUT control signal generator 26, a timing controller 27, and a timer 28.

The sequence controller 21 is connected to the signal generation controller 3, and controls start to end of a test in accordance with descriptions of a test pattern. The timer 28 for time management is connected to the sequence controller 21.

The instruction memory 22 stores various control codes for controlling an address calculation instruction in a test pattern, a data calculation instruction, switching of real-time timings in a test pattern, switching of a pin selector, and generation of a strobe and a I/O switching pattern.

The address generator 23 outputs X and Y addresses that are addresses of the devices in accordance with the address calculation instruction of the test pattern. The address prescrambler 24 converts consecutive addresses generated from the address calculation into addresses of a spare cell.

The data generator 25 outputs the write data and comparison data to the device in accordance with the data calculation instruction of the test pattern.

The DUT control signal generator 26 generates a swap cycle (SWAP) signal that switches the pattern within one cycle.

The timing controller 27 outputs a rate signal serving as a reference timing as a pulse. The rate signal defines a reference timing for waveform output and outputs pulses in very short time periods. The waveform is output by changing an edge by delaying a predetermined timing with respect to the rate signal.

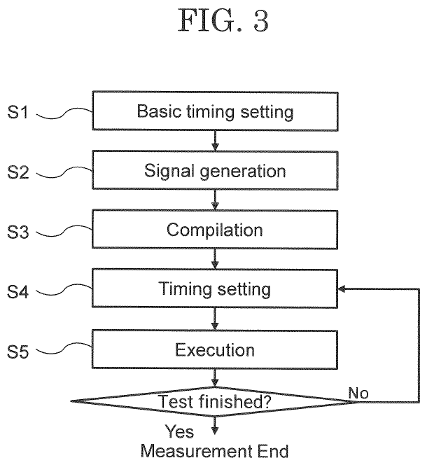

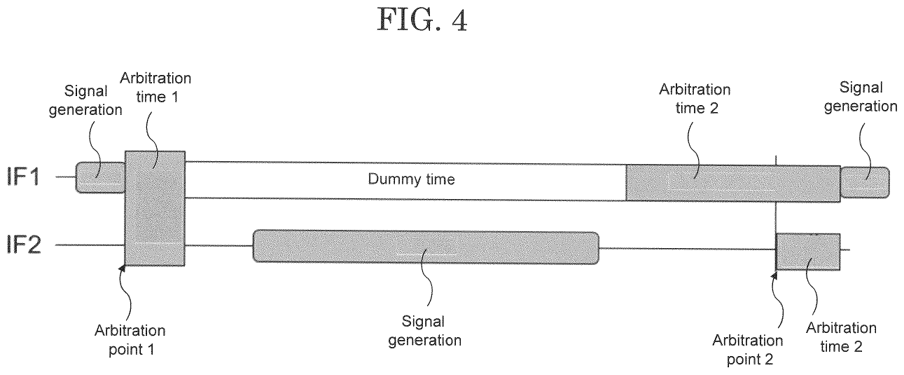

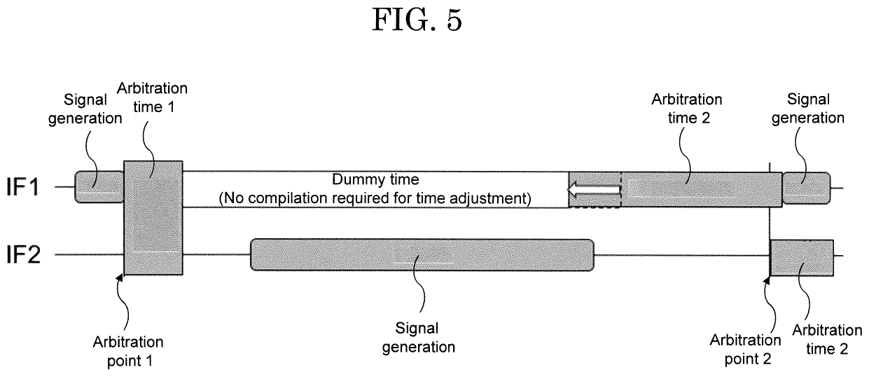

FIG. 3 is a flowchart for explaining execution of a device test by the semiconductor testing apparatus according to the present embodiment. FIG. 4 and FIG. 5 are timing charts for explaining signal generation by the semiconductor testing apparatus according to the present embodiment. The signal generation controller 3 is a control CPU, a main program is loaded onto a memory, and a device test is performed based on the main program.

As shown in FIG. 3, the signal generating controller 3 first sets basic timing information for a test item (content) to be measured in basic timing setting S1. The basic timing information may be timing information determined by a standard.

In signal generation S2, a signal of pattern information is generated based on the basic timing information set in the basic timing setting S1. The pattern information may be pattern information determined by a standard.

In compilation S3, a source code signal including the basic timing information and the pattern information generated by the signal generation S2 is compiled into a data signal to be output to the signal generator 2.

In timing setting S4, the timing information based on the data signal compiled by the compilation S3 is set. The timing information may be arbitrary timing information, for example, timing information for synchronizing with a data signal to be transmitted to another signal generator 2.

In execution S5, the timing information set by the timing setting S4 and the data signal compiled by the compilation S3 are transmitted to the signal generator 2. The signal generator 2 generates a waveform from the input timing information and the data signal and outputs the waveform to the DUT 4.

FIG. 4 is a timing chart showing an IF 1 and an IF 2 of the DUT 4. As shown in FIG. 4, the IF 1 and the IF 2 of the DUT 4 are waveforms (gray) based on different data signals. The input to the IF 1 further includes a dummy time (white) that is set by the timing information. In FIG. 4, the dummy time is added between arbitration time 1 and arbitration time 2 of the IF 1 to adjust the time until synchronization with the IF 2 at an arbitration point 2. However, the present disclosure is not limited thereto, and for example, the dummy time may be added to both waveforms of the IF 1 and the IF 2 in the case where time differences between the IF 1 and the IF 2 are short. The waveform (gray) based on the data signal inputted to each of the IF 1 and the IF 2 can be synchronized by adjusting the timing by adding the dummy time (white) set by the timing information.

As shown in FIG. 3, it is possible to use the data signal compiled in the compilation S3 by repeating the timing setting S4 and the execution S5 until the measurement of the device test is completed. The timing setting S4 can adjust the timing sequentially by setting the timing information each time based on the compiled data signal even if the content of the signal changes.

FIG. 5 is a timing chart showing the IF 1 and the IF 2 of the DUT 4. As shown in FIG. 5, each dummy time is set based on each timing information set in each timing setting S4. By adjusting each dummy time (white) of the data signal independently, the synchronization can be performed while maintaining the waveform (gray) based on the data signal.

In the semiconductor testing apparatus 1 according to the present embodiment, the signal generation controller 3 performs the timing setting S4 after the compilation S3, so that the compiled data signal and the timing information can be separated from each other, and the dummy time can be independently adjusted. As a result, the data signal can be reused just by adjusting the dummy time, and there is no need to repeat the signal generation S2 and the compilation S3 each time, so that the test time of the semiconductor apparatus can be improved.

Note that the embodiment of the present invention may be implemented in the manner described below.

A signal generation controller is configured to compile a signal including basic timing information and pattern information for a test item to be measured into a data signal, and adjust a timing of a test signal by setting timing information based on the data signal.

While certain embodiments have been described, these embodiments have been presented by way of example only, and are not intended to limit the scope of the disclosures. These novel embodiments can be implemented in various other forms, and various omissions, replacements, and modifications can be made without departing from the gist of the disclosure. This embodiment is included in the scope and gist of the disclosure, and is included in the disclosure described in the claims and the equivalent range thereof.

What is claimed is:

1. A semiconductor testing apparatus comprising:
a plurality of signal generators configured to apply test signals to each of a plurality of interfaces of a device under test; and
a signal generation controller configured to compile a signal including basic timing information and pattern information for a test item to be measured into a data signal, and perform timing adjustment of a test signal by setting timing information based on the data signal.

2. The semiconductor testing apparatus according to claim 1, wherein the plurality of signal generators are configured to generate different waveforms.

3. The semiconductor testing apparatus according to claim 1, wherein the plurality of signal generators are configured to generate the test signals from the data signal and the timing information.

4. The semiconductor testing apparatus according to claim 3, wherein the test signals are synchronized by a timing adjustment.

5. The semiconductor testing apparatus according to claim 1, wherein the plurality of signal generators includes a sequence controller, an instruction memory, an address generator, an address prescrambler, a data generator, a DUT control signal generator, a timing controller, and a timer,
wherein the sequence controller is connected to the signal generation controller, and controls start to end of a test in accordance with descriptions of a test pattern,
wherein the timer for time management is connected to the sequence controller,
wherein the instruction memory stores various control codes for controlling an address calculation instruction in a test pattern, a data calculation instruction, switching of real-wherein time timings in a test pattern, switching of a pin selector, and generation of a strobe and a I/O switching pattern,
wherein the address generator outputs X and Y addresses that are addresses of the devices in accordance with the address calculation instruction of the test pattern,
wherein the address prescrambler converts consecutive addresses generated from the address calculation into addresses of a spare cell,
wherein the data generator outputs the write data and comparison data to the device in accordance with the data calculation instruction of the test pattern, the DUT control wherein signal generator generates a swap cycle signal that switches the pattern within one cycle, and
wherein the timing controller outputs a rate signal serving as a reference timing as a pulse.

6. The semiconductor testing apparatus according to claim 5, wherein the rate signal defines a reference timing for waveform output and outputs pulses in first time periods, and wherein the waveform is output by changing an edge by delaying a predetermined timing with respect to the rate signal.

7. A signal generating method comprising:
compiling a signal including basic timing information and pattern information for a test item to be measured into a data signal;
setting timing information based on the data signal; and
generating a waveform from the data signal and the timing information.

8. The signal generating method according to claim 7, wherein the setting timing information and generating a waveform are repeated until the measurement of the test item is completed.

9. The signal generating method according to claim 7, wherein the setting timing information is configured to adjust the timing sequentially by setting the timing information each time based on the compiled data signal during the content of the signal changes.

10. The signal generating method according to claim 7, wherein the setting timing information is performed after the compiling a signal including basic timing information and pattern information.

11. The signal generating method according to claim 10, wherein the compiled data signal and the timing information configured to be separated from each other.

12. A semiconductor test signal generating apparatus comprising:
a compiler configured to compile a signal including basic timing information and pattern information for a test item to be measured into a data signal;
a timing setter configured to set timing information based on the data signal; and
a generator configured to generate a waveform from the data signal and the timing information.

13. The semiconductor test signal generating apparatus according to claim 12, further comprising:
a sequence controller, an instruction memory, an address generator, an address prescrambler, a data generator, a DUT control signal generator, a timing controller, and a timer, and
wherein the sequence controller is connected to the signal generation controller, and controls start to end of a test in accordance with descriptions of a test pattern,
wherein the timer for time management is connected to the sequence controller,
wherein the instruction memory stores various control codes for controlling an address calculation instruction in a test pattern, a data calculation instruction, switching of real-wherein time timings in a test pattern, switching of a pin selector, and generation of a strobe and a I/O switching pattern,
wherein the address generator outputs X and Y addresses that are addresses of the devices in accordance with the address calculation instruction of the test pattern,
wherein the address prescrambler converts consecutive addresses generated from the address calculation into addresses of a spare cell,
wherein the data generator outputs the write data and comparison data to the device in accordance with the data calculation instruction of the test pattern, the DUT control wherein signal generator generates a swap cycle signal that switches the pattern within one cycle, and
wherein the timing controller outputs a rate signal serving as a reference timing as a pulse.

14. The semiconductor test signal generating apparatus according to claim 12, wherein the setting timing information and generating a waveform are repeated until the measurement of the test item is completed.

15. The semiconductor test signal generating apparatus according to claim 12, wherein the setting timing information is configured to adjust the timing sequentially by setting the timing information each time based on the compiled data signal during the content of the signal changes.

16. The semiconductor test signal generating apparatus according to claim 12, wherein the setting timing information is performed after the compiling a signal including basic timing information and pattern information.

17. The semiconductor test signal generating apparatus according to claim 12, wherein the compiled data signal and the timing information configured to be separated from each other.
